(19) United States
(12) Patent Application Publication
(10) Pub. No.: US 2005/0212419 A1
(43) Pub. Date: Sep. 29, 2005

(54) Encapsulating oled devices

(75) Inventors: Fridrich Vazan, Pittsford, NY (US); Amalkumar P. Ghosh, Rochester, NY (US); George R. Olin, Webster, NY (US); Jeffrey P. Serbicki, Holley, NY (US); Joseph E. Yokajty, Webster, NY (US); Steven A. Van Slyke, Pittsford, NY (US)

Correspondence Address: Pamela R. Crocker;Patent Legal Staff, Eastman Kodak Company, 343 State Street, Rochester, NY, 14650-2201, US

(73) Assignee: Eastman Kodak Company

(21) Appl. No.: 10/807,486

(22) Filed: Mar. 23, 2004

(51) Int. Cl. H05B 33/00

(52) U.S. Cl. 313/512; 313/504

(57) ABSTRACT

A method of encapsulating a plurality of OLED devices formed on a common substrate includes stacking a number of repeating assemblies of patterned layers over the OLED devices while leaving outermost portions of electrical interconnects of such encapsulated devices accessible for connecting electrical leads thereto.

### FIELD OF THE INVENTION

The present invention relates to protecting OLED devices from ambient moisture. More particularly, the present invention provides a method of concurrently encapsulating a plurality of OLED devices formed on a common substrate by forming a number of repeating assemblies of patterned layers over the devices so that a display area and portions of electrical interconnects of each OLED device are encapsulated.

### BACKGROUND OF THE INVENTION

Organic light-emitting diode (OLED) devices, also referred to as organic electroluminescent (EL) devices, have numerous well known advantages over other flat-panel display devices currently in the market place. Among these advantages are brightness of light emission, relatively wide viewing angle, reduced electrical power consumption compared to, for example, liquid crystal displays (LCDs) using backlighting, and a wider spectrum of colors of emitted light in full-color OLED displays.

Applications of OLED devices include active matrix image displays, passive matrix image displays, and area lighting devices such as, for example, selective desktop lighting devices. Irrespective of the particular OLED device configuration tailored to these broad fields of applications, all OLEDs function on the same general principles. An organic electroluminescent (EL) medium structure is sandwiched between two electrodes. At least one of the electrodes is light transmissive. These electrodes are commonly referred to as an anode and a cathode in analogy to the terminals of a conventional diode. When an electrical potential is applied between the electrodes so that the anode is connected to the positive terminal of a voltage source and the cathode is connected to the negative terminal, the OLED is said to be forward biased. Positive charge carriers (holes) are injected from the anode into the EL medium structure, and negative charge carriers (electrons) are injected from the cathode. Such charge carrier injection causes current flow from the electrodes through the EL medium structure. Recombination of holes and electrons within a zone of the EL medium structure results in emission of light from this zone that is, appropriately, called the light-emitting zone or interface. The emitted light is directed towards an observer, or towards an object to be illuminated, through the light transmissive electrode. If the light transmissive electrode is between the substrate and the light emissive elements of the OLED device, the device is called a bottom-emitting OLED device. Conversely, if the light transmissive electrode is not between the substrate and the light emissive elements, the device is referred to as a top-emitting OLED device. So-called “transparent” OLED devices are also known in the art that emit light through both the top electrode and through the substrate.

The organic EL medium structure can be formed of a stack of sublayers that can include small molecule layers and polymer layers. Such organic layers and sublayers are well known and understood by those skilled in the OLED art.

Unprotected or neat OLED display devices, irrespective of device configuration, are prone to relatively rapid degradation of performance due to adverse effects of moisture present in the ambient environment. Additionally, unprotected devices can be subject to mechanical damage caused by abrasion. Various efforts have been directed at providing packaged OLED displays in which the packaging approaches offer improved operational lifetime of displays which is, however, still limited so that widespread adoption of OLED display devices is currently restricted.

Haskal et al. disclose in U.S. Pat. No. 5,952,778 an encapsulated organic light-emitting device having an improved protective covering comprising a first layer of passivating metal, a second layer of an inorganic dielectric material, and a third layer of polymer. The device of Haskal et al. is a bottom-emitting passive matrix device which can include an optional impact resistant layer of glass or metal formed over the third layer of a hydrophobic polymer. The first layer of passivating metal is a patterned layer formed contiguous with the cathode electrodes of the device. The second and third layers and the impact resistant layer are formed as uniform unpatterned layers.

Affinito, in U.S. Pat. No. 6,268,695, discloses an environmental barrier for an OLED device. The environmental barrier has a foundation and a cover. Both the foundation and the cover have a top of three layers of a first polymer layer, a ceramic layer, and a second polymer layer. The foundation and/or the cover can have at least one set of an intermediate barrier, each having an intermediate polymer layer with an intermediate ceramic layer thereon. The foundation has a substrate upon which at least a top is deposited. An OLED is constructed upon the top. The cover of at least a top is then placed over the OLED. Each layer of the foundation and the cover is preferably vacuum deposited.

Weaver, in U.S. patent application Publication Ser. No. 2002/0140347 A1, discloses cooperative barrier layers for reducing lateral diffusion of moisture and oxygen in organic optoelectronic devices. A covered substrate comprises a flexible substrate layer on which a plurality of cooperative barrier layers are disposed. The barrier layers comprise one or more planarizing layers and one or more high-density layers. At least one high-density layer extends to the substrate layer and cooperates with the substrate layer to completely surround the at least one planarizing layer. When combined with an additional barrier region, such covered substrates are effective for enclosing organic optoelectronic devices such as, for example, organic light-emitting diodes.

Therefore, a need exists for a manufacturing process of encapsulating a plurality of OLED devices formed on a common substrate wherein the process includes encapsulating a display area and portions of electrical interconnects of each OLED device at the same time.

### SUMMARY OF THE INVENTION

It is an object of the present invention to provide a method of concurrently encapsulating a plurality of OLED devices formed on a common substrate.

It is another object of the present invention to provide a method of concurrently encapsulating a plurality of OLED devices formed on a common substrate by encapsulating a display area and portions of electrical interconnects of each one of the plurality of devices.

It is a further object of the present invention to provide a method of concurrently encapsulating a plurality of OLED devices formed on a common substrate by stacking repeating assemblies of layers formed in a pattern over each one of the plurality of devices.

It is another object of the present invention to provide an encapsulated OLED display having very low water permeability.

These and other objects are achieved by a method of concurrently encapsulating OLED devices against moisture penetration, comprising:
a) providing a rigid substrate or a flexible substrate;
b) forming a plurality of laterally spaced OLED devices on the substrate wherein each OLED device includes a display area and one or more electrical interconnect areas for electrically addressing the display area;
c) forming a polymer layer over the OLED devices and over the substrate surrounding the OLED devices;
d) depositing in a first pattern a particular inorganic dielectric material over the polymer layer and in alignment with the display area of each OLED device to form a first dielectric layer at least over such display area, and wherein the inorganic dielectric material is not deposited in at least a portion of the electrical interconnect areas;
e) removing the polymer layer by dry etching to expose the substrate and the one or more electrical interconnect areas while retaining the polymer layer over the display area of each OLED device due to an etching resistance of the first dielectric layer;
f) depositing in a second pattern the particular dielectric material or a different inorganic dielectric material and in alignment with the display area of each OLED device to form a first dielectric encapsulation layer over the first dielectric layer and over sidewalls of the first dielectric layer and of the polymer layer, thereby providing a plurality of encapsulated OLED devices and permitting electrical access to outermost portions of the one or more electrical interconnect areas of each OLED device; and
g) singulating the OLED devices from the substrate to provide a plurality of individual encapsulated devices.

### BRIEF DESCRIPTION OF THE DRAWINGS

FIG. 1 is a schematic top view of a plurality of neat OLED devices formed on a rigid and moisture impermeable substrate;

FIG. 2A is a schematic sectional view of two neighboring pixels of a pixelated display area of a passive matrix OLED device;

FIG. 2B is a schematic sectional view of two neighboring pixels of a pixelated display area of an active matrix OLED device;

FIG. 3 is a schematic sectional view of two OLED devices shown in FIG;

FIGS. 4A-4H indicate schematically a process sequence in forming encapsulated OLED devices in accordance with aspects of the present invention, in which

FIG. 4A depicts forming a first polymer layer over the OLED devices and over a rigid substrate;

FIG. 4B shows a first dielectric layer deposited in a first pattern over the polymer layer and in alignment with the display areas;

FIG. 4C indicates removing the polymer layer by dry etching from areas not protected by the patterned first dielectric layer;

FIG. 4D shows a second dielectric layer deposited in a second pattern over the first dielectric layer and over sidewalls of the first dielectric layer and of the polymer layer, thereby completing a first assembly of layers;

FIGS. 4E-4H show schematically stacking a second assembly of layers over the first assembly by repeating the process sequence shown in FIGS. 4A-4D, wherein the second assembly encapsulates the first assembly;

FIG. 5 is a schematic top view of a plurality of OLED devices having stacked assemblies of layers for encapsulating display areas and portions of electrical interconnects;

FIG. 6A is a schematic perspective view of an encapsulated top-emitting OLED device which has been singulated from a substrate, and shown operative to emit light from a pixel through the encapsulation assemblies;

FIG. 6B is a schematic perspective view of an encapsulated bottom-emitting OLED device which has been singulated from a substrate, and shown operative to emit light from a pixel through a transparent substrate;

FIGS. 7A-7I indicate schematically a process sequence of forming encapsulated OLED devices over an encapsulated flexible and moisture permeable plastic substrate, in accordance with aspects of the present invention, wherein

FIG. 7A is a schematic sectional view of a flexible plastic polymer substrate;

FIG. 7B indicates forming at least one inorganic dielectric base layer over the substrate;

FIG. 7C depicts forming a polymer layer over the dielectric base layer;

FIG. 7D shows a first dielectric layer deposited in a first pattern over the polymer layer;

FIG. 7E indicates removing the polymer layer by dry etching from areas not protected by the patterned first dielectric layer;

FIG. 7F shows a second dielectric layer deposited in a second pattern over the first dielectric layer and over sidewalls of the polymer layer and of the first dielectric layer, thereby completing a first base assembly of patterned layers;

FIG. 7G indicates schematically forming a plurality of OLED devices with each OLED device formed over the patterned base assembly of layers;

FIGS. 7H-7I show schematically the forming of a first assembly of layers over the OLED devices, in which

FIG. 7H depicts the intermediate state of forming the assembly wherein a polymer layer has been removed by dry etching from areas not protected by a first pattern of a first inorganic dielectric layer; and

FIG. 7I shows a second dielectric layer deposited in a second pattern over the first dielectric layer and over sidewalls of the first dielectric layer and of the polymer layer, thereby completing a first assembly of layers for encapsulating display areas and portions of electrical interconnects of the OLED devices; and

FIG. 8 is a flow chart showing major process elements of the inventive method of encapsulating OLED devices formed on a rigid substrate or formed over an encapsulated flexible polymer substrate;

FIG. 9 is a plan view of a single OLED device on a substrate;

FIG. 10A is a cross sectional view of the OLED device and substrate from FIG. 9 taken along line A-A;

FIG. 10B shows polymer layer deposited over the OLED device and over free surface area of the substrate;

FIG. 10C shows the deposition of a patterned inorganic layer through a shadow mask;

FIG. 11A shows the OLED device and substrate after removal of portions of the polymer layer to form a patterned polymer layer underneath the inorganic layer;

FIGS. 11B and 11C illustrate some possible sidewall angles that can be formed in the patterned polymer layer;

FIG. 12 shows the encapsulated OLED device having an inorganic dielectric layer deposited over the inorganic layer and over the sidewalls of the patterned polymer layer; and

FIG. 13 shows the encapsulated OLED device with a second set of polymer and inorganic layers.

The drawings are necessarily of a schematic nature since layer thicknesses are frequently in the sub-micrometer range and pixel dimensions can be in a range of from 5-250 micrometer, while lateral dimensions of substrates can be in a range of from 10-50 centimeter. Accordingly, the drawings are scaled for ease of visualization rather than for dimensional accuracy.

### DETAILED DESCRIPTION OF THE INVENTION

As used herein, the terms “light transmissive” and “transparent” can be employed interchangeably, and refer to substrates, anode electrodes, cathode electrodes, and encapsulation layers or assemblies of layers having an optical transmission of at least 30% of light generated within an OLED device and directed perpendicularly at each of such members. Preferably, the optical transmission is at least 50%, and more preferably, it is at least 80%. The term “opaque” refers to substrates, anode electrodes, cathode electrodes, and metallic layers (when used in forming an assembly of layers) having an optical transmission of less than 1% of light generated within an OLED device and directed perpendicularly at each of such members. The term “pixel” is generally used to designate the smallest individually addressable element of a pixelated OLED device, and denotes herein the light-emitting portion of a pixel.

Although not shown, in order to preserve the visual clarity of the drawings, it will be understood that forming layers or assemblies of layers is achieved by condensing a polymer material, a dielectric material, or a metal material from a vapor phase in a chamber held at a reduced pressure. When a layer is to be formed in a pattern, a shadow mask having openings corresponding to such pattern is positioned proximate a surface on which such patterned layer is to be formed.

Because moisture can adversely affect performance and operational lifetime of neat, i.e. unencapsulated, OLED devices, care is taken to maintain the devices in a moisture-free environment until the OLED devices are fully encapsulated. Accordingly, in the drawings showing process sequences of encapsulating OLED devices, or of forming OLED devices, it should be considered that the devices are contained in a chamber held at a reduced pressure or in another moisture-free enclosure.

Useful techniques of forming layers of a material from a vapor phase of such material include, but are not limited to, thermal physical vapor deposition, sputter deposition, electron beam deposition, chemical vapor deposition, plasma-enhanced chemical vapor deposition, laser-induced chemical vapor deposition, and atomic layer deposition.

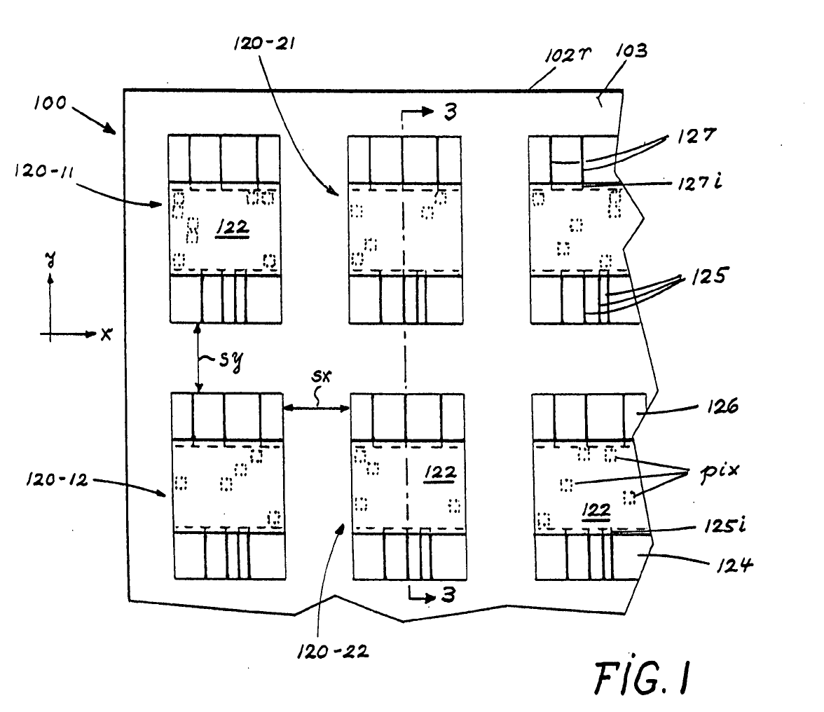

Turning to FIG. 1, a top view shows schematically an OLED device configuration 100 having a plurality of OLED devices 120 formed over a first surface 103 of a rigid and moisture impermeable common substrate 102r. The OLED devices are arranged in a two-dimensional array, and are laterally spaced by a spacing sx along an x-direction and by a spacing sy along a y-direction. In practice, the spacings sx and sy are selected to be as small as practical so that the plurality of devices having a given size or area can be increased on a substrate of a selected size or area, providing that such spacings permit subsequent singulation of encapsulated OLED devices from the substrate 102r.

Four OLED devices within the array are identified at 120-11 (corresponding to a position 1;1 in the array), 120-12, 120-21, and 120-22 (corresponding to a position 2;2 in the array).

Each OLED device includes a display area 122. The display area can contain an array of light-emitting pixels, for example, as one might use in a light-emitting display. Alternatively, display area 122 can contain a single light emitting pixel or region, for example, as one might use in a backlight for an LCD display. For the purposes of this discussion, the display area 122 shown in FIG. 1 is pixilated having pixels “pix”. Only a few pixels are depicted in dotted outline to preserve visual clarity of the drawing. Each OLED device 120 is shown here as having two electrical interconnect areas, namely first and second interconnect areas 124 and 126. It will be appreciated that other OLED device configurations can include devices having electrical interconnect areas disposed in three or four positions around the pixelated display areas 122.

The first electrical interconnect area 124 includes outer portions 125 of electrical interconnects which extend inwardly into the display area 122 as inner portions 125i. Similarly, the second electrical interconnect area 126 includes electrical interconnects having outer portions 127 and inner portions 127i. The outer portions 125, 127 are used for attaching electrical leads, which connect an operative OLED device to external power and control electronics. The inner portions 125i and 127i are electrical addressing elements, which direct electrical drive signals and control signals from the outer portions to each pixel pix of the display area 122.

The OLED devices 120 can be constructed in the form of passive matrix OLED devices which, in turn, can be bottom-emitting or top-emitting devices. Alternatively, the OLED devices 120 can be top-emitting or bottom-emitting active matrix devices. Designs and fabrication processes of such varied OELD devices are known to those skilled in this art. Accordingly, fabrication processes per se of OLED devices are only incidental to the present invention of encapsulating OLED devices.

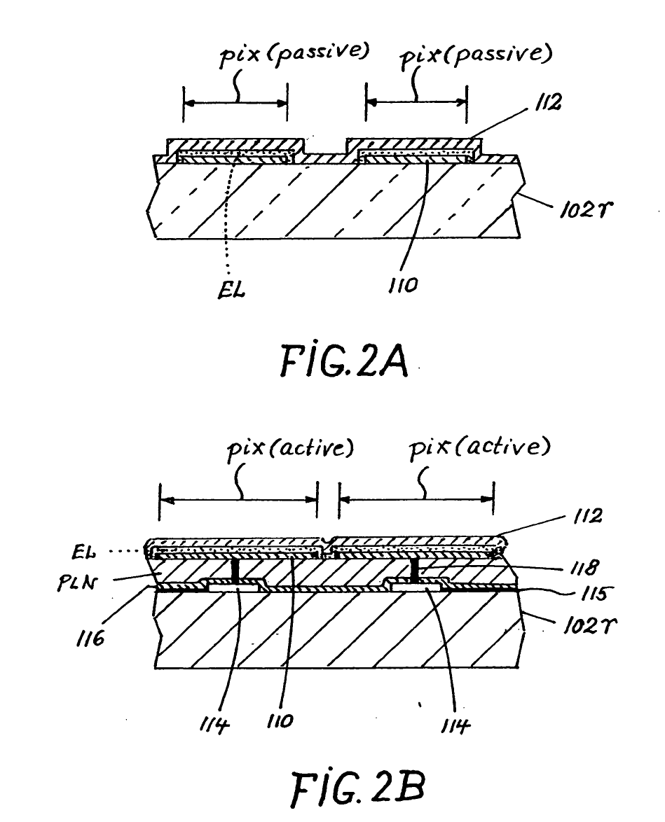

FIGS. 2A and 2B are laterally expanded sectional views of two neighboring pixels pix of a pixelated display area of a passive matrix OLED device and of an active matrix OLED device, respectively. The pixels pix (passive) and pix (active) are simplified illustrative examples to indicate basic features of such pixels. A rigid substrate 102r is shown. In each of the two pixel configurations, an organic electroluminescent medium structure EL is sandwiched between an anode electrode 110 and a cathode electrode 112, one of which is light transmissive. The distinguishing aspects between pix (passive) and pix (active) relate to electrical signal addressing of the electrodes to generate light within the organic EL medium structure.

In FIG. 2A, anode electrodes 110 and cathode electrodes 112 are formed in perpendicular directions, and electrical drive signals are applied sequentially between each anode electrode and a selected cathode electrode to generate light in an actuated pixel pix (passive) whenever an anode electrode is temporally at a more positive electrical potential with respect to a cathode electrode.

In FIG. 2B, pixels pix (active) include a common cathode electrode 112, and each anode electrode 110 sequentially receives an electrical drive signal via an anode connector 118 from an electrical addressing and driving element 114 which can include thin-film transistors, a capacitor, and associated electrical wiring. In the simplest form shown here, internal electrical conductor 115 provides control signals to the addressing and driving elements 114. The conductors 115 are depicted as being formed on the substrate 102r. An inorganic dielectric layer 116 is formed over the conductors 115, the addressing and driving elements 114, and over the substrate between the elements 114. A planarizing layer PLN provides a planar surface for depositing the anode electrodes 110.

In various designs of passive matrix and active matrix OLED devices, internal electrical interconnects, or internal electrical conductors 115, are provided in the form of multi-level interconnects or conductors, with each level separated from an adjacent level by an electrically insulative layer. Electrical connections between conductors at different levels, and between conductors and pixel electrodes 110, 112 are made through vias or openings produced in a particular insulative layer in a manner known to those skilled in the art of fabricating multi-level conductors and interconnects.

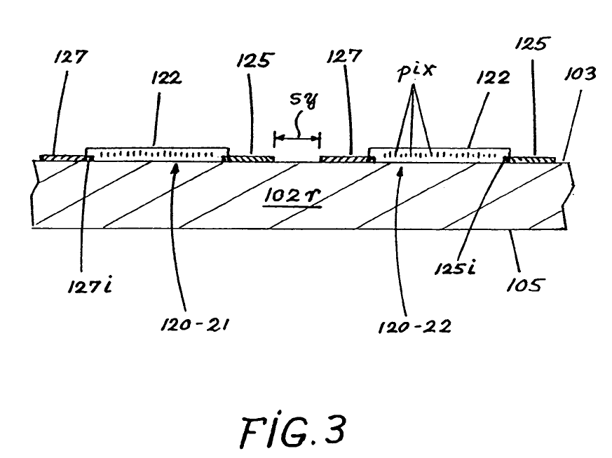

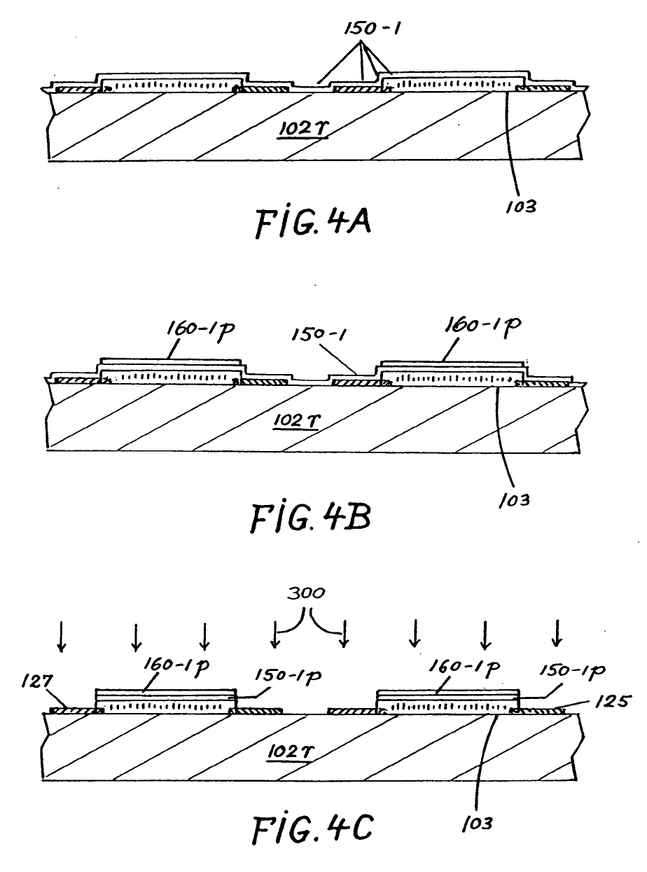

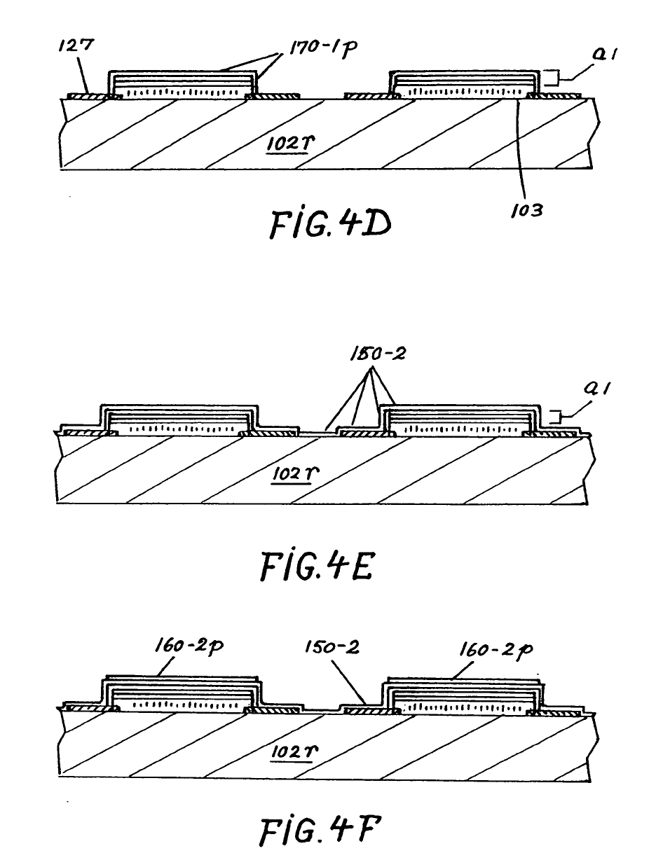

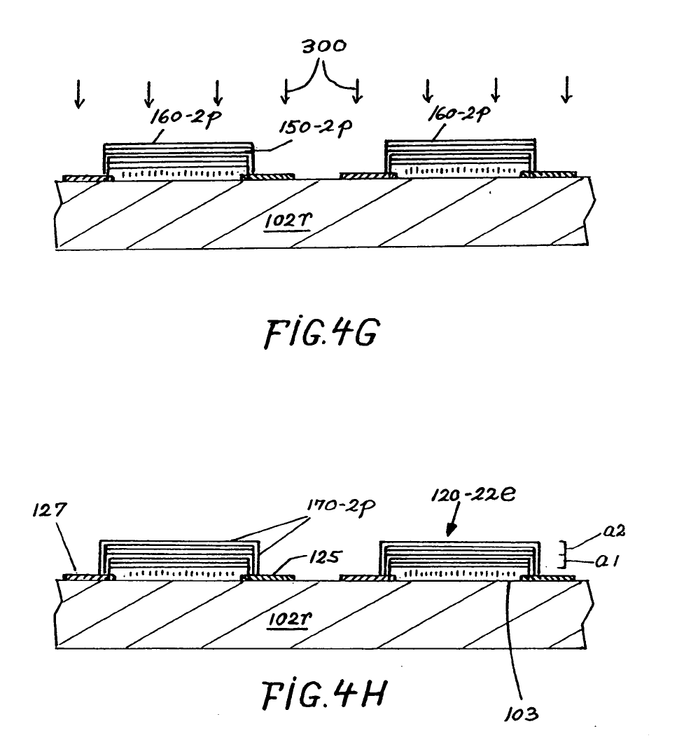

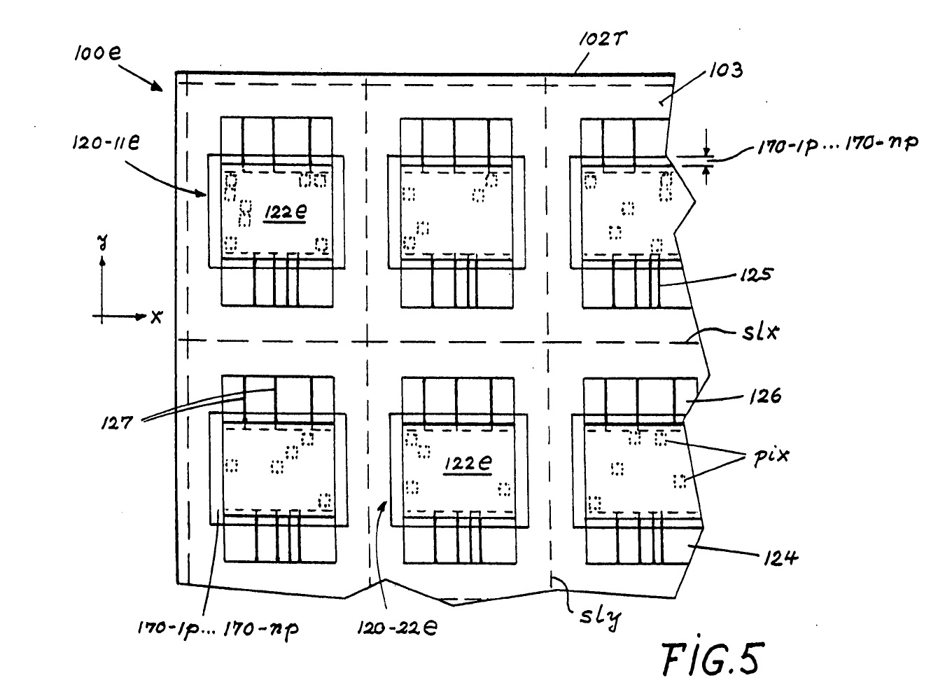

Turning to FIG. 3, a sectional view of two OLED devices 120-21 and 120-22 is shown, taken along the section lines 3-3 of FIG. 1. The pixelated display areas 122 are indicated schematically, as are the inner portions 125i and 127i of the electrical interconnects. First and second substrate surfaces 103 and 105, respectively, of the substrate 102r are shown. The drawing of FIG. 3 is used in the following FIGS. 4A-4H to detail the inventive process sequence of forming repeating assemblies of layers provided in patterns for encapsulating the display areas 122 and portions of the electrical interconnects 125 and 127.

In FIG. 4A, a first polymer layer 150-1 is formed over the OLED devices and over the first substrate surface 103 surrounding the OLED devices. Preferred polymer materials for forming the first polymer layer and subsequently formed polymer layers include parylene materials which can be deposited from a vapor phase to provide a polymer layer having a relatively small number of defects, excellent adhesion to, and step coverage over, topological features of the OLED devices. However, polymer layers formed of a parylene material or of another organic material or composites of organic materials, exhibit moisture permeability which is higher in a lateral direction and in a thickness direction than a layer formed of an inorganic dielectric material or a layer formed of a metal. Thus, a polymer layer such as the layer 150-1, and particularly a patterned polymer layer such as the patterned first polymer layer 150-1p (see FIG. 4C) has to be fully encapsulated to minimize or to limit moisture penetration through sidewalls of the polymer layer and through the layer in a thickness direction. Polymer layers can be formed at a thickness in range of from 0.5 to 5 micrometer.

In FIG. 4B, a first layer 160-1p of a particular or selected inorganic dielectric material has been deposited in a pattern over the first polymer layer 150-1, with the pattern of layer 160-1p formed in alignment with the display areas 122 (see FIGS. 1, 3) of the OLED devices.

The pattern of the first dielectric layer 160-1p is formed by condensing inorganic dielectric material from the vapor phase onto the first polymer layer 150-1 through openings in a shadow mask, which is positioned proximate to, or in contact with, the protruding portions of the polymer layer 150-1, and the openings of the shadow mask corresponding to the pattern of the dielectric layer 160-1p to be formed.

Suitable examples of inorganic dielectric materials for forming the first dielectric layer and subsequent dielectric layers include aluminum oxide, silicon dioxide, silicon nitride, silicon oxynitride, indium-tin oxide, diamond-like carbon, and composite materials such as, for example, zinc sulfide:silicon dioxide.

Such inorganic dielectric materials can form inorganic dielectric layers by condensing from the vapor phase in deposition processes which include thermal physical vapor deposition, sputter deposition, chemical vapor deposition, plasma-enhanced chemical vapor deposition, laser-induced chemical vapor deposition, induction-assisted chemical vapor deposition, electron-beam assisted vapor deposition, and atomic layer deposition processes. Inorganic dielectric layers deposited by such processes can have a thickness in a range of from 10 nm to several hundred nanometer.

In FIG. 4C, a dry etching gas stream 300 is schematically indicated as being directed toward the surfaces of the configuration of FIG. 5B. The dry etching gas stream contains oxygen or is entirely oxygen, such as ionized oxygen derived in or from an oxygen plasma.

Reactive oxygen species such as ionized oxygen species can be used effectively to decompose and to remove organic materials from areas of an organic layer which are not protected by an etch mask which is provided here in the form of the patterned first dielectric layer 160-1p, and offering substantial etching resistance to the reactive oxygen species of the dry etching gas stream 300. Thus, the polymer layer 150-1 of FIG. 4B is transformed into a patterned first polymer layer 150-1p in FIG. 4C with the pattern being substantially congruent with the pattern of the first layer 160-1p of the inorganic dielectric material. Electrical interconnects 125, 127, and substrate areas surrounding such interconnects are now free from polymer material.

FIG. 4D depicts a completed first assembly a1 of layers upon depositing a first encapsulation layer 170-1p of the particular or selected inorganic dielectric material used in depositing the first dielectric layer 160-1p, or by selecting a different inorganic dielectric material. This first encapsulation layer is deposited through openings in a shadow mask, with the openings selected so that upper surfaces (not identified in the drawings) of the layer 160-1p and sidewalls of this first dielectric layer and of the patterned first polymer layer 150-1p are fully encapsulated. The first encapsulation layer has its sidewalls extending to cover portions of the electrical interconnects 125 and 127 and in sealing contact therewith, and extending over portions of the substrate and in sealing contact therewith. The first encapsulation layer 170-1p should be selected to have low electrical conductivity to prevent shorting between electrical interconnects.

FIGS. 4E-4H show a process sequence of forming a repeating second assembly a2 of layers over the first assembly a1.

In FIG. 4E, a second polymer layer 150-2 has been deposited over the first assembly a1 of layers, over the interconnects, and over areas on the first substrate surface 103 surrounding the interconnects by repeating the deposition process described with reference to FIG. 4A.

In FIG. 4F, a second layer 160-2p of a particular inorganic dielectric material is shown deposited in a pattern over the second polymer layer 150-2 wherein the pattern is aligned with respect to sidewalls (not identified in the drawings) of the first encapsulation layer 170-1p (see FIG. 4D).

In FIG. 4G, a dry etching gas stream 300 is directed at the surfaces of the configuration of FIG. 4F to remove the second polymer layer 150-2 from areas not protected by the pattern of the second layer 160-2p which also serves as an etch mask in the same manner as described above with reference to FIG. 4C. Thus, a patterned second polymer layer 150-2p is achieved.

Finally, in FIG. 4H, a completed second assembly a2 of layers is obtained upon depositing in a pattern a second encapsulation layer 170-2p of a particular or selected inorganic dielectric material. The layer 170-2p encapsulates all previously deposited layers and including the sidewalls of the first encapsulation layer 170-1p (see FIG. 4D). The second encapsulation layer 170-2p has its side walls extending to cover an additional portion of the electrical interconnects 125, 127 in sealing contact therewith. An encapsulated OLED device 120-22e is indicated in FIG. 4H.

Effective encapsulation of OLED devices against moisture penetration can be achieved by forming only a first assembly a1 of layers over the devices. In order to provide additional protection and related extended operational lifetime of OLED devices, stacking two or more repeating assemblies of layers can be performed. Indeed, n assemblies of layers, an, can be stacked using the inventive method where n is an integer which can be, for example, 2, 3, 4, or 5.

Turning to FIG. 5, a top view of an encapsulated OLED device configuration 100e is shown. Two encapsulated OLED devices are indicated at 120-11e and 120-22e. The encapsulated devices have encapsulated pixelated display areas 122e, and encapsulation layers 170-1p . . . 170-np extend sealingly into portions of the electrical interconnects 125 and 127 and laterally beyond the display areas 122e onto the substrate surface 103 and in sealing contact therewith. Singulation lines s1x along an x-direction and singulation lines s1y along a y-direction are shown schematically in dashed outline on the substrate 102r.

If the neat OLED devices of FIG. 1 are designated to be bottom-emitting devices, the rigid substrate 102r has to be transparent, and at least portions of the anode electrodes 110 (see FIGS. 2A and 2B) need to be transparent. In such bottom-emitting configuration, one or more of the first, second, or n-th layers 160-1p, 160-2p, or 160-np deposited in a pattern can be replaced by a metal layer deposited in a corresponding pattern through openings in shadow masks. Such metal layers are equally effective as etch masks in the process of dry etching the underlying polymer layer(s).

Examples of metals from which a metal layer can be formed by deposition from a vapor phase include, but are not limited to, aluminum, gold, silver, tantalum nitride, titanium nitride, and tungsten. Various known methods of depositing metal layers can be used.

In bottom-emitting OLED devices, the rigid substrate 102r is provided in the form of a moisture impermeable glass plate. In top-emitting OLED devices, the rigid substrate 102r is provided in the form of a moisture impermeable glass plate, a metal plate, or a ceramic plate.

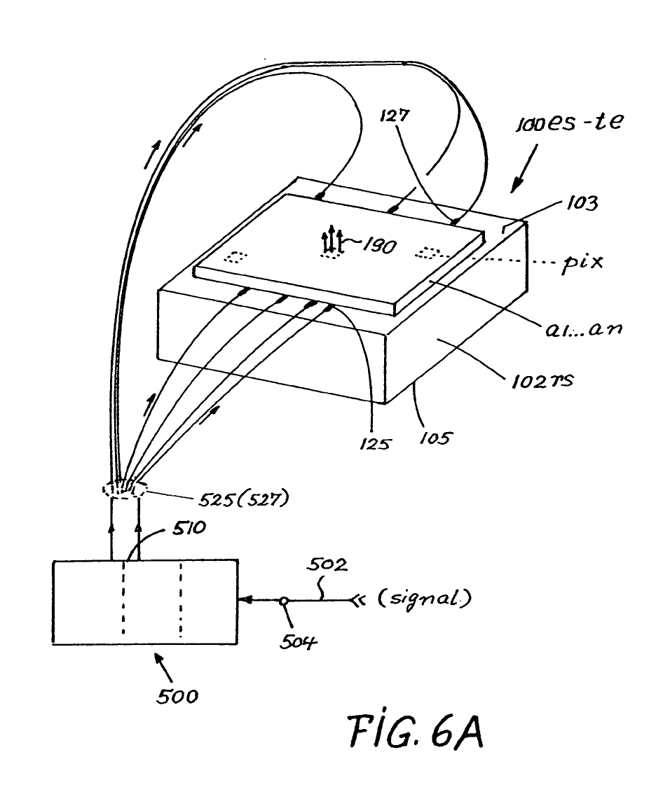

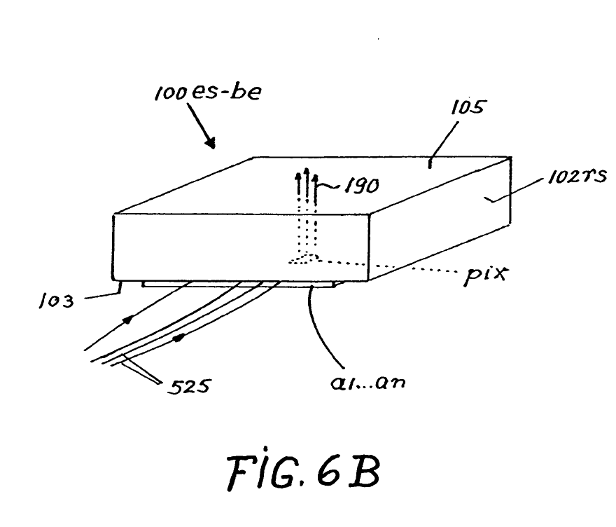

FIG. 6A is a schematic perspective view of one of a plurality of encapsulated top-emitting OLED devices 100es-te obtained by singulating devices from the encapsulated OLED device configuration 100e of FIG. 5 and having a plurality of top-emitting OLED devices.

The singulated rigid substrate 102rs has been singulated along the singulation lines s1x and s1y indicated in FIG. 5.

Light emission 190 from a pixel pix is directed toward an observer through the transparent stacked repeating assemblies of layers a1 . . . an. Light emission, of any one pixel at an instant of time, occurs in response to electrical drive signals and electrical control signals provided at outermost portions of the electrical interconnects 125 and 127 by electrical leads 525 (527) connected thereto. Electrical leads 525 (527) are the output leads issuing from an output terminal 510 of a power supply, scan line generator, and signal processor 500 which, in turn, receives an input signal at an input terminal 504 via a signal lead 502.

FIG. 6B is a schematic perspective view of one of a plurality of encapsulated bottom-emitting OLED devices 100es-be obtained by singulating devices from the encapsulated OLED device configuration 100e of FIG. 5 and having a plurality of bottom-emitting OLED devices.

Light emission 190 from a pixel pix is directed toward an observer through the second surface 105 of the transparent singulated rigid substrate 102rs. The device 100es-be is operative in the same manner as described above with reference to FIG. 6A. In order to maintain visual clarity of FIG. 6B, only portions of electrical leads 525 are shown.

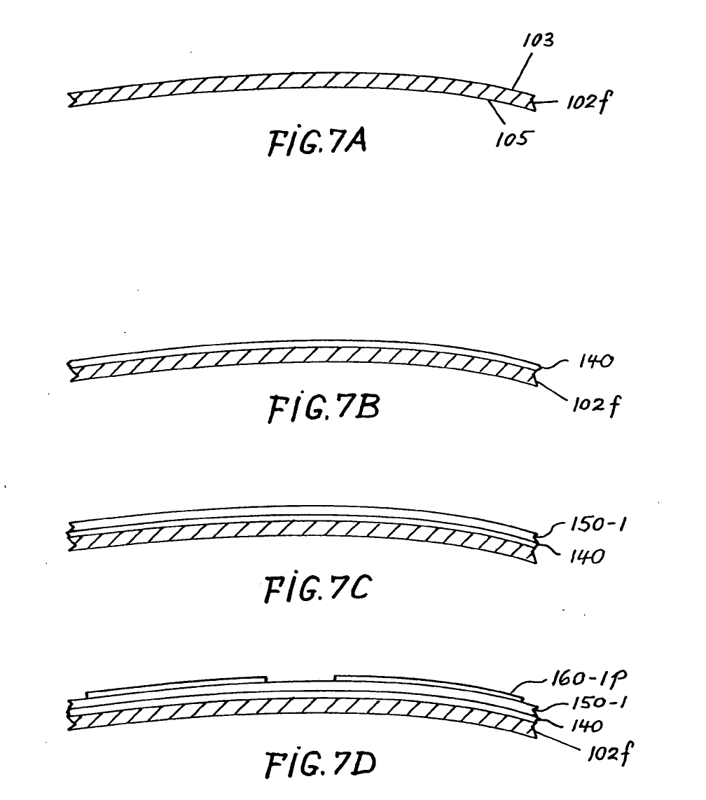

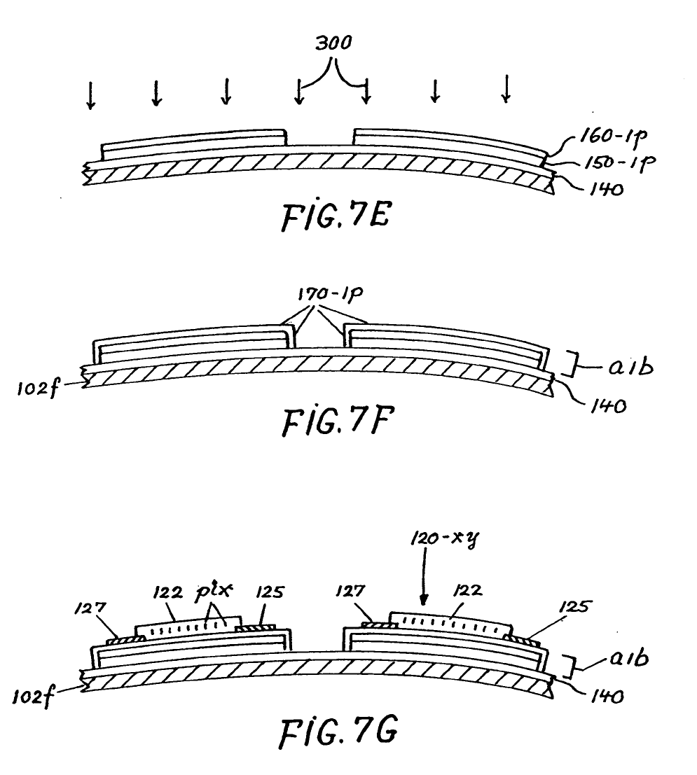

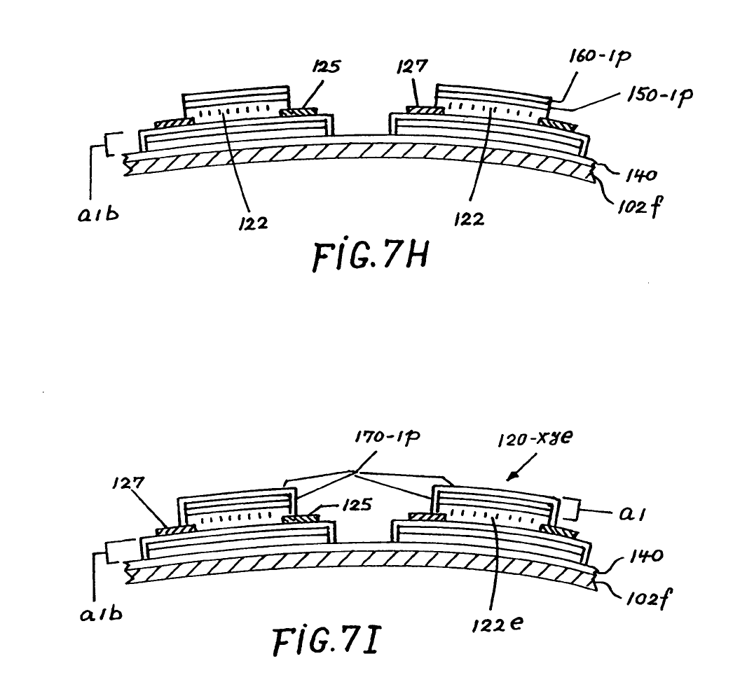

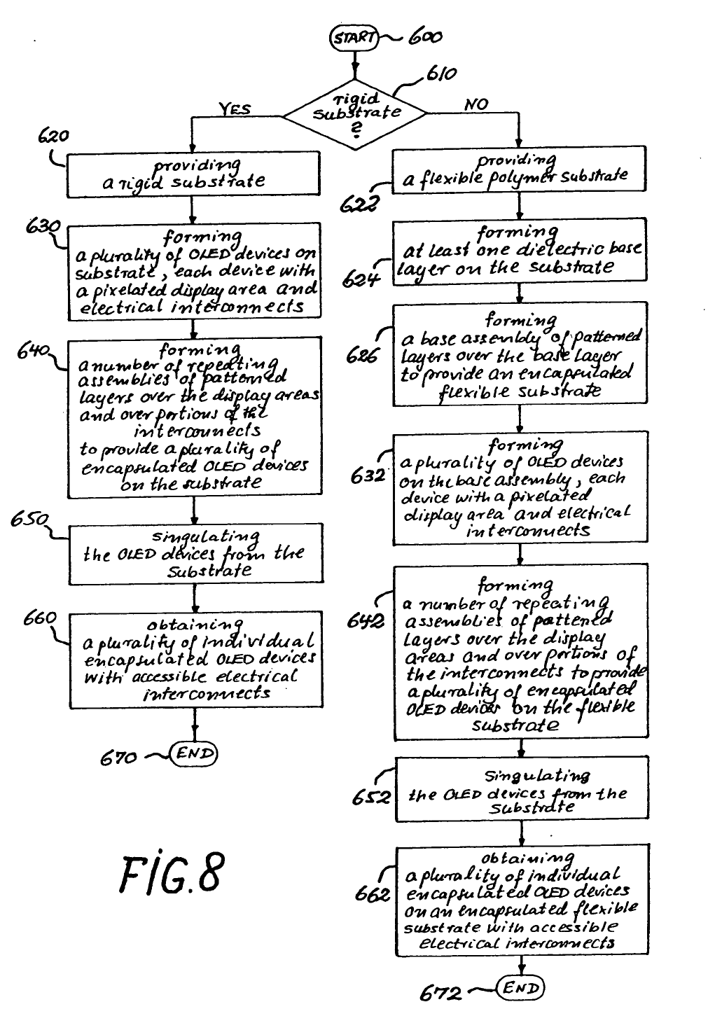

Turning to FIGS. 7A-7F, schematic sectional views show a process sequence of forming over a first surface 103 of a flexible substrate 102f, in sequence, an inorganic dielectric base layer, and a base assembly of layers over the base layer.

FIG. 7A depicts a flexible substrate 102f having first and second surfaces 103 and 105, respectively. The flexible substrate 102f is provided in the form of a moisture permeable plastic material selected from polymer materials.

In FIG. 7B, an inorganic dielectric base layer 140 has been formed over the first substrate surface 103 to provide a moisture barrier over this surface. At least one dielectric base layer 140 is required, but more than one such base layer can be formed by sequentially depositing selected inorganic dielectric materials from a vapor phase.

In FIG. 7C, a polymer layer 150-1 has been formed over the dielectric base layer 140. The polymer layer 150-1 is preferably made from a parylene material which can be deposited as a layer from a vapor phase of the material.

In FIG. 7D, a particular or selected inorganic dielectric material has been deposited in a first pattern over the polymer layer 150-1 to form a patterned first dielectric layer 160-1p, with the pattern (“p”) in alignment with OLED devices to be formed subsequently.

FIG. 7E shows schematically the dry etching process by which the polymer layer 150-1 of FIG. 7D is removed by a dry etching gas stream 300 to expose the dielectric base layer 140 while retaining the polymer layer as a patterned polymer layer 150-1p under the patterned inorganic dielectric layer 160-1p which serves as an etching mask as described previously with respect to removing a polymer layer by dry etching.

In FIG. 7F, a first base assembly a1b of layers has been completed upon depositing in a second pattern the particular dielectric material or a different inorganic dielectric material and in alignment with the first pattern of the first dielectric layer to form a first dielectric encapsulation layer 170-1p over the first dielectric layer 160-1p and over sidewalls of the first dielectric layer and of the polymer layer. Sidewalls (not identified in the drawings) of the first encapsulation layer 170-1p extend to the dielectric base layer 140 and are in sealing contact therewith. At least one such base assembly a1b of layers is required.

FIG. 7G depicts a configuration in which a plurality of laterally spaced OLED devices have been formed over the first dielectric encapsulation layer 170-1p (or over the first base assembly a1b of layers).

One of the plurality of OLED devices is indicated at 120-xy in correspondence with a position (x;y) within a two-dimensional array of devices. Each one of the OLED devices includes a pixelated display area 122 having pixels pix, and electrical interconnects 125 and 127. These OLED devices are substantially identical in all respects to the devices formed on the previously described rigid substrate 102r.

FIGS. 7H and 7I show schematically an abbreviated process sequence of forming a first assembly a1 of layers over the display area 122 and over a portion of the electrical interconnects 125 and 127.

In FIG. 7H, a first polymer layer 150-1p has been patterned by dry etching (not shown) in which a first inorganic dielectric layer 160-1p, deposited in a pattern (“p”) provided an etch mask during removing the polymer material from areas not protected by the layer 160-1p.

FIG. 7I shows a completed assembly a1 of layers upon depositing in a pattern a first dielectric encapsulation layer 170-1p which encapsulates the layer 160-1p of FIG. 7H and sidewalls of the layer 160-1p and of the polymer layer 150-1p. Side walls (not identified) of the encapsulation layer 170-1p extend over portions of the electrical interconnects 125 and 127 and are in sealing contact therewith.

Thus, a plurality of encapsulated OLED devices are provided on an encapsulated flexible substrate. It will be understood that a number of repeating stacked base assemblies of layers can be formed, as well as a number of repeating stacked assemblies of layers for encapsulating the OLED devices. One of the encapsulated OLED devices is indicated at 120-xye, corresponding to a position x;y in a two-dimensional array.

If the OLED devices are designated as bottom-emitting devices, the flexible substrate 102f, the dielectric base layer 140, and the base assembly a1b of layers are transparent elements. In this bottom-emitting configuration, the first dielectric layer 160-1p (see FIG. 7H) can be replaced by a metal layer having an identical pattern and providing equally effective resistance to etching by the dry etching process used for forming a patterned polymer layer.

If the OLED devices are designated as top-emitting devices, the flexible substrate 102f can be provided in the form of an optically opaque polymer material. Alternatively, or additionally, the first dielectric layer 160-1p of the base assembly a1b of layers can be replaced by a metal layer having an identical pattern and serving equally effectively as an etch mask during dry etching used for forming a patterned polymer layer of a base assembly of layers. In this top-emitting configuration, the assembly a1 of layers, or a number of stacked repeating assemblies, have to be optically transparent to light generated within the organic EL medium structure of an OLED device.

A plurality of individual encapsulated OLED devices on an encapsulation flexible substrate can be obtained by singulating devices from the substrate through the dielectric base layer 140, wherein each singulated device has accessible outermost portions of electrical interconnects 125 and 127.

Turning to FIG. 8, a flow chart indicates major process elements of the present invention.

The process starts at 600. Element 610 provides for selecting a type of substrate. If a rigid substrate is provided in element 620, element 630 includes forming a plurality of OLED devices, each device having a pixelated display area and electrical interconnects. Element 640 includes forming a number of repeating assemblies of patterned layers over the display areas and over portions of the interconnects to provide a plurality of encapsulated OLED devices on the substrate. Element 650 includes singulating the encapsulated OLED devices from the substrate. In element 660, a plurality of individual encapsulated OLED devices are obtained, each device having accessible electrical interconnects. The process ends at 670.

If a flexible polymer substrate is provided in element 622, element 624 includes forming at least one dielectric base layer on the substrate. Element 626 includes forming at least one base assembly of patterned layers over the base layer to provide an encapsulated flexible substrate. Element 632 includes forming a plurality of OLED devices on the base assembly, each device having a pixelated display area and electrical interconnects. Element 642 includes forming a number of repeating assemblies of patterned layers over the display areas and over portions of the interconnects to provide a plurality of encapsulated OLED devices on the flexible substrate. Element 652 includes singulating the encapsulated OLED devices from the substrate. In element 662, a plurality of individual encapsulated OLED devices are obtained on an encapsulated flexible substrate, each device having accessible electrical interconnects. The process ends at 672.

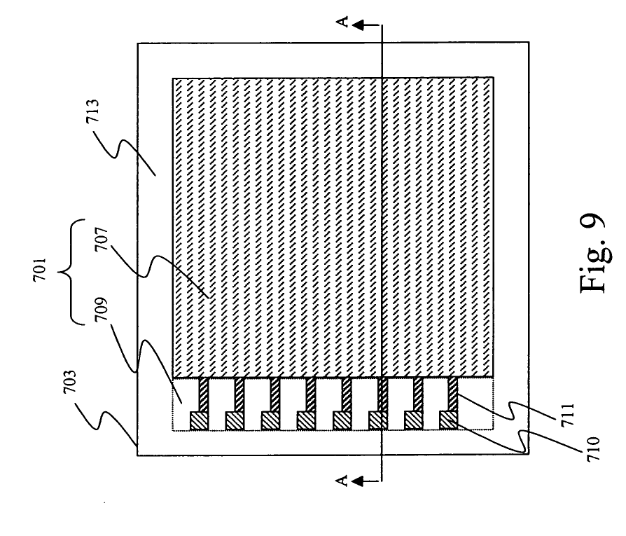

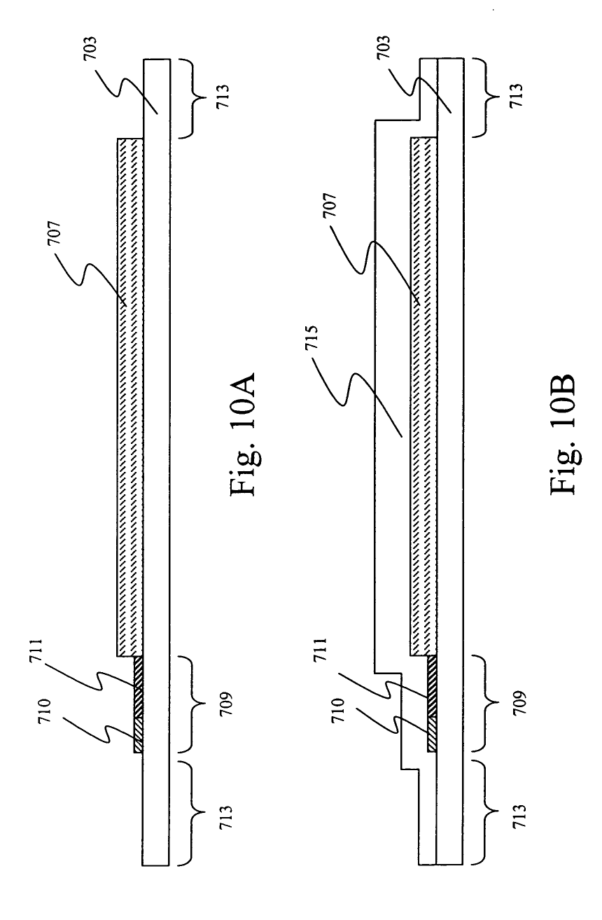

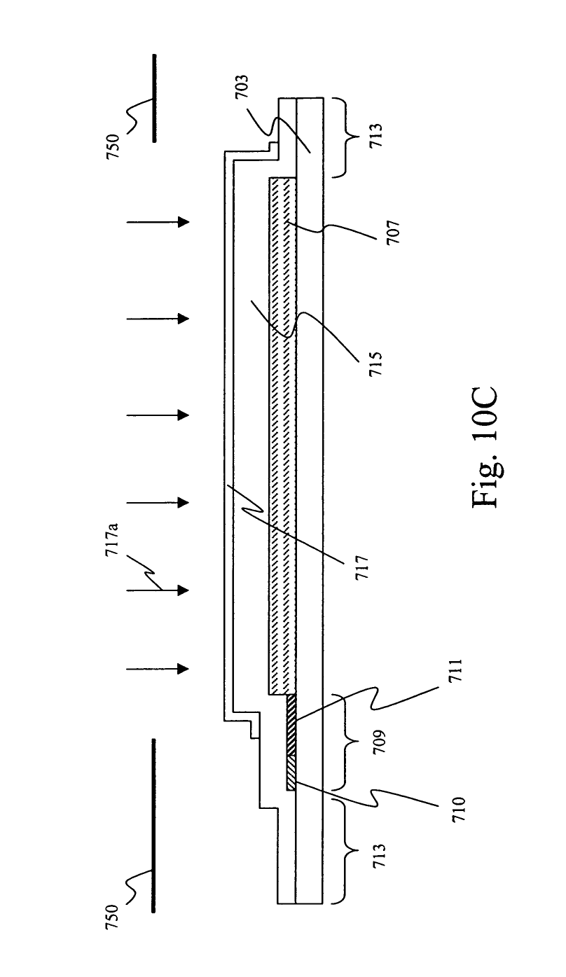

Another embodiment of the present invention is shown in FIGS. 9-12 where a single OLED device is encapsulated against moisture penetration. FIG. 9 shows a plan view of an OLED device 701 provided over substrate 703 having a surface 705. The OLED device 701 includes a display area 707 and one or more electrical interconnect areas 709 for electrically addressing the display area. The electrical interconnect areas can contain connector pads 710 and electrical leads 711. There remains a free surface area 713 of the substrate surface not occupied by the OLED device 701. The OLED device 701 can be an active or passive matrix device. OLED device 701 can be fabricated using methods and materials well known in the art and described previously. FIG. 10A shows a cross section of the OLED device taken along line A-A.

As shown in FIG. 10B, a polymer layer 715 is formed over both the OLED device and the free surface area of the substrate. The polymer layer may be applied from a solution, but is preferably formed by condensation of a vapor phase material in a reduced pressure chamber, e.g., parylene. Although not limited, it is contemplated that a polymer layer thickness of 0.5 to 5 micrometers is a useful range. As shown in FIG. 10C, over the top surface of polymer layer 715, an inorganic material is provided in a pattern to form an inorganic layer 717. Inorganic layer 717 can have a thickness in a range of from a few nanometers to several hundred nanometers.

Conveniently, the inorganic material 717a is a dielectric material having low electrical conductivity. Suitable examples of inorganic dielectric materials for forming inorganic layer 717 and subsequent dielectric layers include aluminum oxide, silicon dioxide, silicon nitride, silicon oxynitride, indium-tin oxide, diamond-like carbon, and composite materials such as, for example, zinc sulfide:silicon dioxide. Such inorganic dielectric materials can be deposited by thermal physical vapor deposition, sputter deposition, chemical vapor deposition, plasma-enhanced chemical vapor deposition, laser-induced chemical vapor deposition, induction-assisted chemical vapor deposition, electron-beam assisted vapor deposition, and atomic layer deposition processes.

Alternatively, the inorganic material 717a can be a metal, metal alloy, or a metallic compound. Examples of such materials include, but are not limited to, aluminum, gold, silver, molybdenum, tantalum nitride, titanium nitride, and tungsten. Various known methods of depositing metal layers can be used.

Inorganic layer 717 can be patterned by depositing the inorganic material 717a through a shadow mask 750. Other methods of patterning the inorganic layer may be used, such as lift-off technology. All of the polymer layer in the display area is covered with the inorganic layer 717, and at least a portion of the polymer layer in the electrical interconnect area and at least a portion of the polymer layer over the free surface area of the substrate are not covered with the inorganic layer.

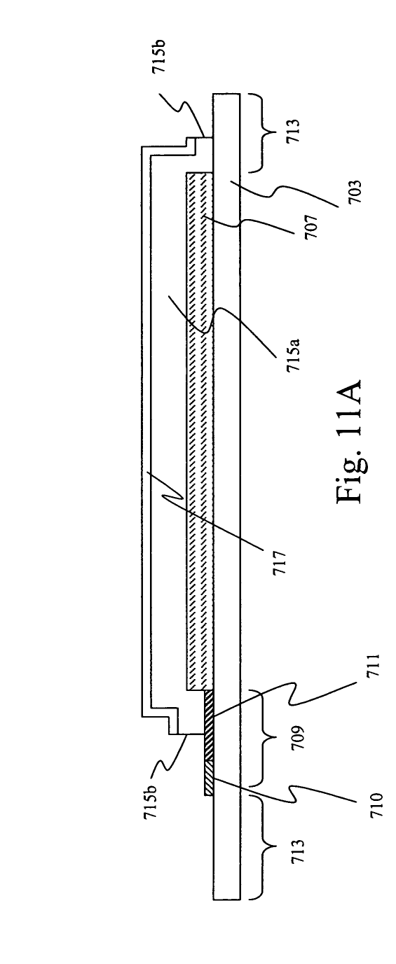

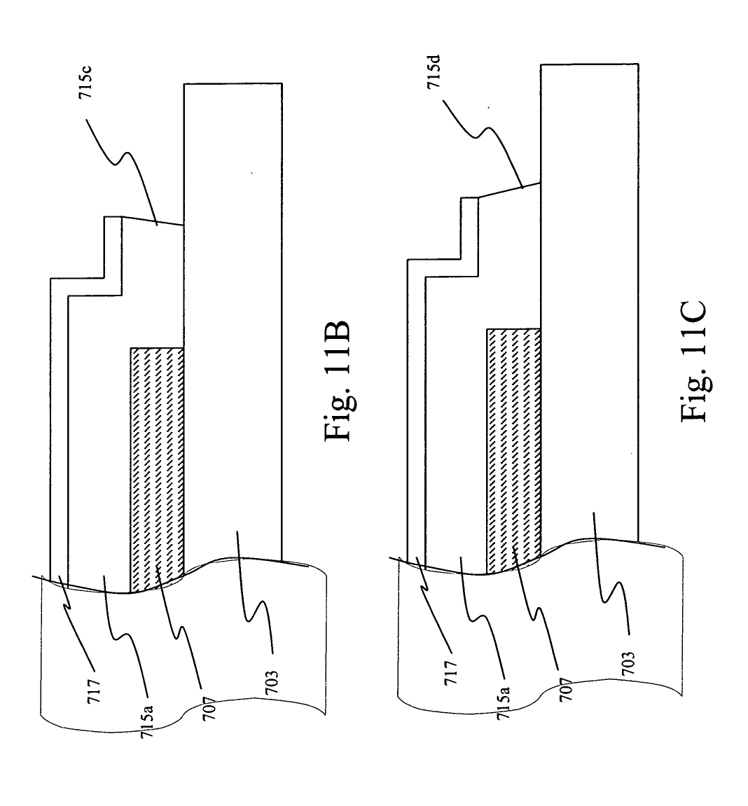

As shown in FIG. 11A, after the inorganic layer 717 has been deposited, the polymer is removed from areas not covered by the inorganic layer 717, for example, by dry etching where the inorganic layer 717 acts as an etch mask. The patterned polymer layer 715a is substantially congruent with the inorganic layer 717 with respect to its pattern. Other methods may also be used to remove the polymer, such as laser ablation or wet chemical etching, but dry etching is generally preferred. Although vertical sidewalls 715b are shown for the patterned polymer layer 715a for illustrative purposes, they may be angled inwardly (715c) as shown in FIG. 11B, outwardly (715d) as shown in FIG. 11C, or they may have some other shape.

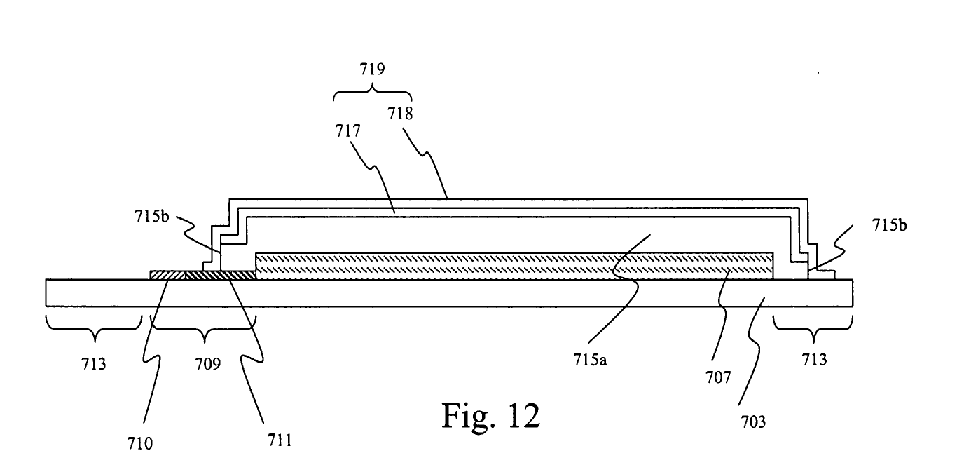

As shown in FIG. 12, after the polymer has been removed in areas not covered by the inorganic layer, an inorganic dielectric layer 718 is deposited in a second pattern that extends at least over the sidewalls of the inorganic layer and over the sidewalls of the polymer layer. The inorganic dielectric layer may be formed of the same material as the inorganic layer if the inorganic layer was made from a dielectric material, or it may be different. The inorganic dielectric layer should be made from a dielectric material having low electrical conductivity. Suitable examples of inorganic dielectric materials for forming inorganic dielectric layer 718 and subsequent dielectric layers include aluminum oxide, silicon dioxide, silicon nitride, silicon oxynitride, diamond-like carbon, and composite materials, for example, zinc sulfide:silicon dioxide. Inorganic dielectric layer 718 is conveniently patterned using a shadow mask, but other patterning methods may be used such as lift-off technology.

The combination of inorganic layer 717 and inorganic dielectric layer 718 create an inorganic dielectric assembly 719 that seals the polymer layer and the OLED device from moisture penetration. It is critical that the sidewalls of the patterned polymer layer 715a be coated with the inorganic dielectric layer. If the patterned polymer layer sidewall is undercut relative to the inorganic layer, e.g. as in 715c, the deposition conditions selected for the inorganic dielectric layer must ensure conformal coating of these sidewalls.

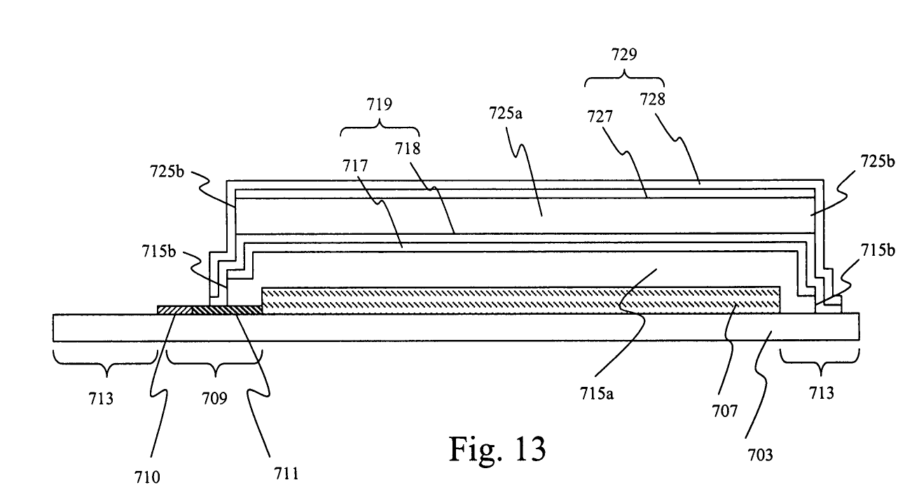

In another embodiment of this invention, as shown in FIG. 13, a second patterned polymer layer 725a can be provided over the first inorganic dielectric assembly 719 in substantially the same pattern and method as the first patterned polymer layer 715a. A second inorganic dielectric layer assembly 729, comprising inorganic layer 727 and inorganic dielectric layer 728, can be provided over the second patterned polymer layer in substantially the same pattern and method as the first inorganic dielectric layer assembly. The sidewalls 725b of the second patterned polymer layer are covered by the inorganic dielectric layer 728. This repeating structure can provide extra moisture protection.

The invention has been described in detail with particular reference to certain preferred embodiments thereof, but it will be understood that variations and modifications can be effected within the spirit and scope of the invention.

### Parts List

100 OLED device configuration

100e encapsulated OLED device configuration

100es-be encapsulated singulated bottom-emitting OLED device

100es-te encapsulated singulated top-emitting OLED device

102f flexible and moisture permeable plastic common substrate

102r rigid and moisture impermeable common substrate

102rs singulated rigid substrate

103 first substrate surface

105 second substrate surface

110 anode electrode(s)

112 cathode electrode(s)

114 electrical addressing and driving elements for pixels in an active matrix OLED device

115 internal electrical conductor(s) of an active matrix OLED device

116 inorganic dielectric layer of an active matrix OLED device

118 anode connector(s) of an active matrix OLED device

120 OLED device(s)

120-11 OLED device at a position 1;1 on a substrate

120-11e encapsulated OLED device at a position 1;1 on a substrate

120-12 OLED device at a position 1;2 on a substrate

120-21 OLED device at a position 2;1 on a substrate

120-22 OLED device at a position 2;2 on a substrate

120-22e encapsulated OLED device at a position 2;2 on a substrate

120-xy OLED device at a position x;y on a substrate

120-xye encapsulated OLED device at a position x;y on a substrate

122 display area(s)

### Parts List (Con't)

122e encapsulated pixelated display area(s)

124 first electrical interconnect area(s)

125 outer portion(s) of electrical interconnect(s)

125i inner portion(s) of electrical interconnect(s)

126 second electrical interconnect area(s)

127 outer portion(s) of electrical interconnect(s)

127i inner portion(s) of electrical interconnect(s)

140 inorganic dielectric base layer (on flexible substrate 102f)

150-1 first polymer layer

150-1p patterned first polymer layer

150-2 second polymer layer

150-2p patterned second polymer layer

160-1p first layer of a particular inorganic dielectric material (160) deposited in a pattern (“p”)

160-2p second layer of the particular inorganic dielectric material (160) deposited in a pattern (“p”)

170-1p first encapsulation layer of a particular inorganic dielectric material (170) deposited in a pattern (“p”)

170-2p second encapsulation layer of the particular inorganic dielectric material (170) deposited in a pattern (“p”)

170-np n-th encapsulation layer of the particular inorganic dielectric material (170) deposited in a pattern (“p”), where n is an integer

190 emitted light

300 dry etching gas stream

500 power supply, scan line generator, and signal processor

502 signal lead

504 input terminal

### Parts List (Con't)

510 output terminal

525 electrical leads

527 electrical leads

600 start of process

610 selecting type of substrate

620 providing rigid substrate(s)

622 providing flexible polymer substrate(s)

624 forming at least one dielectric base layer on substrate

626 forming at least one base assembly of patterned layers over the dielectric base layer

630 forming a plurality of OLED devices (rigid substrate)

632 forming a plurality of OLED devices over base assembly (flexible substrate)

640 forming a number of repeating assemblies of patterned layers to provide encapsulated OLED devices (rigid substrate)

642 forming a number of repeating assemblies of patterned layers to provide encapsulated OLED devices (flexible substrate)

650 singulating OLED devices from the (rigid) substrate

652 singulating OLED devices from the (flexible) substrate

660 obtaining plurality of individual encapsulated OLED devices (rigid substrate)

662 obtaining plurality of individual encapsulated OLED devices on encapsulated flexible substrate

670 end of process (rigid substrate)

672 end of process (flexible substrate)

701 OLED device

### Parts List (Con't)

703 substrate

705 substrate surface

707 display area

709 electrical interconnect area

710 connector pad

711 electrical leads

713 free surface area of substrate

715 polymer layer

715a patterned polymer layer

715b sidewall of patterned polymer layer

715c inwardly angled sidewall of patterned polymer layer

715d outwardly angled sidewall of patterned polymer layer

717 inorganic layer

717a inorganic material

718 inorganic dielectric layer

719 inorganic dielectric assembly

725a second patterned polymer layer

725b sidewall of second patterned polymer layer

727 inorganic layer

728 inorganic dielectric layer

729 second inorganic dielectric assembly

750 shadow mask

a1 first assembly of layers

a1b first base assembly of layers (on flexible substrate 102f)

a2 second assembly of layers

an n-th assembly of layers

EL organic electroluminescent (“EL”) medium structure

### Parts List (Con't)

pix light-emitting portion of a pixel

pix (active) pixel(s) of an active matrix OLED device

pix (passive) pixel(s) of a passive active matrix OLED device

PLN planarizing layer (in an active matrix OLED device)

s1x singulation line(s) along an x-direction

s1y singulation line(s) along a y-direction

sx spacing between OLED devices along an x-direction

sy spacing between OLED devices along a y-direction

x x-direction

y y-direction

1. A method of concurrently encapsulating OLED devices against moisture penetration, comprising:
a) providing a rigid substrate or a flexible substrate;
b) forming a plurality of laterally spaced OLED devices on the substrate wherein each OLED device includes a display area and one or more electrical interconnect areas for electrically addressing the display area;
c) forming a polymer layer over the OLED devices and over the substrate surrounding the OLED devices;
d) depositing in a first pattern a particular inorganic dielectric material over the polymer layer and in alignment with the display area of each OLED device to form a first dielectric layer at least over such display area, and wherein the inorganic dielectric material is not deposited in at least a portion of the electrical interconnect areas;
e) removing the polymer layer by dry etching to expose the substrate and the one or more electrical interconnect areas while retaining the polymer layer over the display area of each OLED device due to an etching resistance of the first dielectric layer;
f) depositing in a second pattern the particular dielectric material or a different inorganic dielectric material and in alignment with the display area of each OLED device to form a first dielectric encapsulation layer over the first dielectric layer and over sidewalls of the first dielectric layer and of the polymer layer, thereby providing a plurality of encapsulated OLED devices and permitting electrical access to outermost portions of the one or more electrical interconnect areas of each OLED device; and
g) singulating the OLED devices from the substrate to provide a plurality of individual encapsulated devices.

2. The method of claim 1 wherein c) through f) are repeated one or more times prior to g).

3. The method of claim 1 wherein a) includes providing the rigid substrate in the form of a moisture impermeable plate of a material selected from glass, metal, and ceramic materials.

4. The method of claim 1 wherein a) includes providing the flexible substrate in the form of a moisture permeable plastic material selected from polymer materials.

5. The method of claim 4 wherein a) further includes
i) forming at least one inorganic dielectric base layer over a surface of the flexible substrate;
ii) forming at least one base assembly of layers over the base layer, forming the at least one base assembly by:
l) forming a polymer layer over the base layer;
m) depositing in a first pattern a particular inorganic dielectric material or a particular metal material over the polymer layer and in alignment with OLED devices to be formed to form a first dielectric layer or metal layer aligned with such OLED devices to be formed;
n) removing the polymer layer by dry etching to expose the at least one dielectric base layer while retaining the polymer layer under the first dielectric layer or metal layer due to an etching resistance of the first dielectric layer or metal layer; and
o) depositing in a second pattern the particular dielectric material or a different inorganic dielectric material and in alignment with the first pattern of the first dielectric layer or the metal layer to form a first dielectric encapsulation layer over the first dielectric layer or metal layer and over sidewalls of the first dielectric layer or metal layer and of the polymer layer; and
p) forming the plurality of laterally spaced OLED devices over the first dielectric encapsulation layer.

6. The method of claim 1 wherein b) includes forming a plurality of top-emitting or bottom-emitting OLED devices.

7. The method of claim 5 further including forming passive matrix or active matrix OLED devices.

8. The method of claim 1 wherein c) includes forming the polymer layer by condensing polymer material from a vapor phase in a chamber held at a reduced pressure.

9. The method of claim 1 wherein d) includes depositing the particular inorganic dielectric material by condensing such material from a vapor phase through openings in a shadow mask with the openings corresponding to the first pattern, and in a chamber held at a reduced pressure.

10. The method of claim 1 wherein e) includes removing the polymer layer by subjecting the layer to a reactive gas stream containing oxygen, and in a chamber held at a reduced pressure.

11. The method of claim 1 wherein f) includes depositing the inorganic dielectric material by condensing such material from a vapor phase through openings in a shadow mask with the openings corresponding to the second pattern, and in a chamber held at a reduced pressure.

12. The method of claim 5 wherein a) includes forming the at least one dielectric base layer by condensing inorganic dielectric material from a vapor phase in a chamber held at a reduced pressure.

13. The method of claim 2 wherein b) includes forming a plurality of top-emitting OLED devices having a transparent cathode electrode or transparent cathode electrodes.

14. The method of claim 5 wherein a) includes forming the at least one dielectric base layer as a transparent layer over the surface of a transparent flexible substrate, and b) includes forming at least one transparent base assembly of layers, and c) includes forming a plurality of bottom-emitting OLED devices having anode electrodes at least portions of which are transparent.

15. A plurality of laterally spaced encapsulated top-emitting or bottom-emitting OLED devices formed on a rigid substrate and made in accordance with the method of claim 1.

16. A plurality of laterally spaced encapsulated top-emitting or bottom-emitting OLED devices formed over an encapsulated flexible polymer substrate and made in accordance with the method of claim 5.

17. A method of concurrently encapsulating OLED devices against moisture penetration, comprising:
a) providing a rigid substrate or a flexible substrate;
b) forming a plurality of laterally spaced OLED devices on the substrate wherein each OLED device includes a display area and one or more electrical interconnect areas for electrically addressing the display area;
c) forming a polymer layer over the OLED devices and over the substrate surrounding the OLED devices;
d) depositing in a first pattern a particular metal material over the polymer layer and in alignment with the display area of each OLED device to form a metal layer at least over such display area, and wherein the metal material is not deposited in at least a portion of the electrical interconnect areas;
e) removing the polymer layer by dry etching to expose the substrate and the one or more electrical interconnect areas while retaining the polymer layer over the display area of each OLED device due to an etching resistance of the metal layer;
f) depositing in a second pattern an inorganic dielectric material in alignment with the display area of each OLED device to form a first dielectric encapsulation layer over the metal layer and over sidewalls of the metal layer and of the polymer layer, thereby providing a plurality of encapsulated OLED devices and permitting electrical access to outermost portions of the one or more electrical interconnect areas of each OLED device; and
g) singulating the OLED devices from the substrate to provide a plurality of individual encapsulated devices.

18. The method of claim 17 wherein a) includes:
i) providing a flexible substrate in the form of a moisture permeable plastic material selected from polymer materials.
ii) forming at least one inorganic dielectric base layer over a surface of the flexible substrate;
iii) forming at least one base assembly of layers over the base layer, forming the at least one base assembly by:
l) forming a polymer layer over the base layer;
m) depositing in a first pattern a particular inorganic dielectric material or a particular metal material over the polymer layer and in alignment with OLED devices to be formed to form a first dielectric layer or metal layer aligned with such OLED devices to be formed;
n) removing the polymer layer by dry etching to expose the at least one dielectric base layer while retaining the polymer layer under the first dielectric layer or metal layer due to an etching resistance of the first dielectric layer or metal layer; and
o) depositing in a second pattern the particular dielectric material or a different inorganic dielectric material and in alignment with the first pattern of the first dielectric layer or the metal layer to form a first dielectric encapsulation layer over the first dielectric layer or metal layer and over sidewalls of the first dielectric layer or metal layer and of the polymer layer; and
d) forming the plurality of laterally spaced OLED devices over the first dielectric encapsulation layer

19. A method of encapsulating an OLED device against moisture penetration, comprising:
a) providing a substrate having a surface;
b) forming an OLED device over a portion of the surface of the substrate wherein the OLED device includes a display area and one or more electrical interconnect areas for electrically addressing the display area, and wherein there remains a free surface area of the of substrate not occupied by the display device;
c) forming a polymer layer over both the OLED device and the free surface area of the substrate;
d) depositing in a first pattern an inorganic layer over the polymer layer such that all of the polymer layer in the display area is covered by the inorganic layer, and at least a portion of the polymer layer in the electrical interconnect area and at least a portion of the polymer layer over the free surface area of the substrate is not covered with the inorganic layer;
e) removing the polymer layer in areas not covered by the inorganic layer to produce a patterned polymer layer; and
f) depositing in a second pattern an inorganic dielectric layer which extends at least over the sidewalls of the inorganic layer and over the sidewalls of the patterned polymer layer.

20. The method of claim 19 wherein e) is accomplished by dry etching.

21. The method of claim 19 wherein c) through f) are repeated one or more times.

22. An OLED display device comprising:
a) a substrate having a surface;
b) an OLED device provided over a portion of the surface of the substrate, wherein the OLED device comprises a display area and an electrical interconnect area;
c) a first patterned polymer layer extending over the entire display area but not over at least a portion of the electrical interconnect area and not over at least a portion of the surface of the substrate that is not occupied by the OLED device; and
d) a first inorganic dielectric layer assembly containing a patterned inorganic layer provided over the top surface of the patterned polymer layer and in alignment with the patterned polymer layer, and an inorganic dielectric layer provided over the inorganic layer and extending over the sidewalls of the inorganic layer and polymer layer, wherein at least a portion of the electrical interconnect area is not covered by the inorganic dielectric layer.

23. The device of claim 22 further including:
e) a second polymer layer provided over the first inorganic dielectric assembly in substantially the same pattern as the first polymer layer; and
f) a second inorganic dielectric layer assembly provided over the second polymer layer in substantially the same pattern as the first dielectric layer assembly.
